(19) United States
(12) Patent Application Publication
(10) Pub. No.: US 2008/0149976 A1
(43) Pub. Date: Jun. 26, 2008

(54) VERTICAL TYPE CMOS IAMGE SENSOR AND METHOD OF MANUFACTURING THE SAME

(76) Inventor: Su Lim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/955,250

(22) Filed: Dec. 12, 2007

(30) Foreign Application Priority Data
Dec. 22, 2006 (KR) 10-2006-0132995

(51) Int. Cl. H01L 27/146; H01L 21/04

(52) U.S. Cl. 257/292; 438/80; 257/E27.134; 257/E21.04

(57) ABSTRACT

A vertical type CMOS image sensor and a method of manufacturing the same including a P⁺-type red photodiode formed in a semiconductor substrate, a first silicon epilayer formed over the semiconductor substrate and including a P⁺-type green photodiode formed therein, a second silicon epilayer formed over the first silicon epilayer and including a P⁺-type blue photodiode formed therein; a first P⁺-type plug formed in the first silicon epilayer and electrically connected to the P⁺-type red photodiode, and a second P⁺-type plug in the second silicon epilayer which is electrically connected to the P⁺-type green photodiode.

The present application claims priority under 35 U.S.C. 119 to Korean Patent Application No. 10-2006-0132995, (filed on Dec. 22, 2006), which is hereby incorporated by reference in its entirety.

### BACKGROUND

One type of semiconductor device is an image sensor which converts an optical image into an electrical signal. The image sensor may be classified into a complementary metal-oxide-silicon (CMOS) image sensor and a charge coupled device (CCD) image sensor. The CCD image sensor has more excellent characteristics in photosensitivity and noise when compared to the CMOS image sensor. The CCD image sensor, however, has difficulty in high integration and has high power consumption. In contrast, the CMOS image sensor has characteristics of a simpler manufacturing process, higher integration, and lower power consumption.

Accordingly, as technology for manufacturing semiconductors device has increased, the manufacturing of CMOS image sensor and characteristics thereof may become greatly improved. A pixel of the CMOS image sensor may include a plurality of photodiodes for receiving light and CMOS elements for controlling image signals received from the photodiodes. The photodiodes generate electron-hole pairs according to the wavelengths and the intensities of red light, green light and blue light input through color filters. An output signal varies depending on the amount of generated electrons. Accordingly, an image can be sensed.

The CMOS image sensor may also include a pixel region, in which photoelectric conversion portions such as photodiodes are formed, and a peripheral circuit region for detecting signals output from the pixel region. The peripheral circuit region may be provided to surround the pixel region.

Among CMOS image sensors, a vertical type CMOS image sensor may include a pixel structure using n+p photodiodes, that is, a structure in which a red photodiode, a green photodiode and a blue photodiode may be vertically implemented in a pixel. Charges may be selectively moved by a corresponding transfer gate Tx. The vertical-type photodiodes which are respectively implemented in epilayers and are output to a final output terminal by an operation of a transistor associated with a pixel.

Accordingly, since the transfer gate Tx, a reset transistor, a source follower, a select transistor have a typical 4-transistor structure in view of a photodiode and a pixel includes an N+p photodiode and an NMOS transistor, such a CMOS image sensor may be weak against photodiode dark current, reset noise, random row noise and flicker noise. Accordingly, image quality of the vertical-type CMOS image sensor may deteriorate.

### SUMMARY

Embodiments relate to a vertical-type CMOS image sensor and a method of manufacturing the same that can prevent occurrence of noise.

Embodiments relate to a method of manufacturing a vertical-type CMOS image sensor that can include at least one of the following steps: forming a first n-type implantation region in the semiconductor substrate by implanting an n-type dopant into the entire surface of the semiconductor substrate; forming a P⁺-type red photodiode in the first n-type implantation region by implanting a dopant therein; forming a first silicon epilayer over the semiconductor substrate including the P⁺-type red photodiode using an epitaxial growth method; forming a first P⁺-type plug extending through the first silicon epilayer and electrically connected to the P⁺-type red photodiode; forming a second n-type implantation region in the first silicon epilayer by implanting an n-type dopant into the entire surface of the first silicon epilayer including the first P⁺-type plug; forming a P⁺-type green photodiode in the second n-type implantation region by implanting a dopant therein; forming a second silicon epilayer over the first silicon epilayer including the P⁺-type green photodiode; performing a shallow trench isolation on the second silicon epilayer to define an active region and form a plurality of device isolation films for forming field regions; forming a plurality of n-well regions by implanting an n-type dopant into the active region between the device isolation films; forming a pair of second P⁺-type plugs extending through the second silicon epilayer and electrically connected to the P⁺-type green photodiode and the first P⁺-type plug by implanting a P⁺-type dopant into the second silicon epilayer; and then forming a P⁺-type blue photodiode in the second silicon epilayer by implanting a dopant into one of the n-well regions between the device isolation films.

Embodiments relate to a method of manufacturing a vertical-type CMOS image sensor that can include at least one of the following steps: forming a first n-type implantation region in a semiconductor substrate; forming a first photodiode in the first n-type implantation region; forming a first silicon epilayer over the semiconductor substrate including the first photodiode; forming a first plug in the first silicon epilayer and electrically connected to the first photodiode; forming a second n-type implantation region in the first silicon epilayer; forming a second photodiode in the second n-type implantation region and electrically connected to the first plug; forming a second silicon epilayer over the first silicon epilayer including the n-type implantation region and the second photodiode; forming a plurality of device isolation films in the second silicon epilayer; forming a plurality of n-type well regions in the second silicon epilayer; forming a pair of second plugs in the second silicon epilayer and electrically connected to second photodiode and first plug; and then forming a third photodiode in one of the n-well regions.

Embodiments relate to a vertical-type CMOS image sensor that can include: a semiconductor substrate; a P⁺-type red photodiode formed in the semiconductor substrate; a first silicon epilayer formed over the semiconductor substrate including the a P⁺-type red photodiode; a P⁺-type green photodiode formed in the first silicon epilayer; a second silicon epilayer formed over the first silicon epilayer including the P⁺-type green photodiode; a P⁺-type blue photodiode formed in the second silicon epilayer; a first P⁺-type plug formed in the first silicon epilayer and electrically connected at one end to the P⁺-type red photodiode and another end to the P⁺-type green photodiode; and a second P⁺-type plug formed in the second silicon epilayer and electrically connected to the P⁺-type green photodiode.

### DRAWINGS

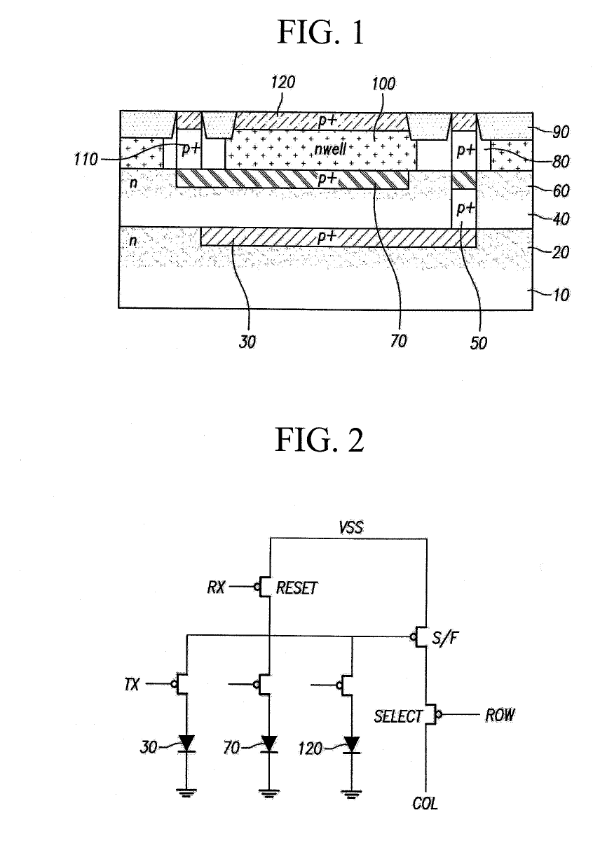

Example FIGS. 1 to 3 illustrate a vertical-type CMOS image sensor, in accordance with embodiments.

### DESCRIPTION

As illustrated in example FIG. 1, a vertical-type CMOS image sensor in accordance with embodiments can include a pixel structure in which a plurality of holes can be used as main carriers in electrons/holes generated at a P⁺N photodiode and are moved through a PMOS transistor. The vertical-type CMOS image sensor can include a structure in which P⁺-type green photodiode 70 and P⁺-type blue photodiode 120 can be respectively provided in n-type epilayers laminated on and/or over semiconductor substrate 10 including P⁺-type red photodiode 30, that is, first silicon epilayer 40 and second silicon epilayer 80, in a substantially vertical direction. In the vertical-type CMOS image sensor, an N+P type photodiode can be replaced with a P⁺N type photodiode in view of the photodiode, and a PMOS transistor can be connected to the vertical-type CMOS image sensor in view of a pixel transistor.

As illustrated in example FIG. 2, in accordance with embodiments, the vertical-type CMOS image sensor transfer gate Tx, reset transistor Rx, source follower S/F, select transistor SELECT can be connected to the vertical type CMOS image sensor implemented by PMOS transistors. Accordingly, noise can be reduced and a low-noise circuit can be achieved.

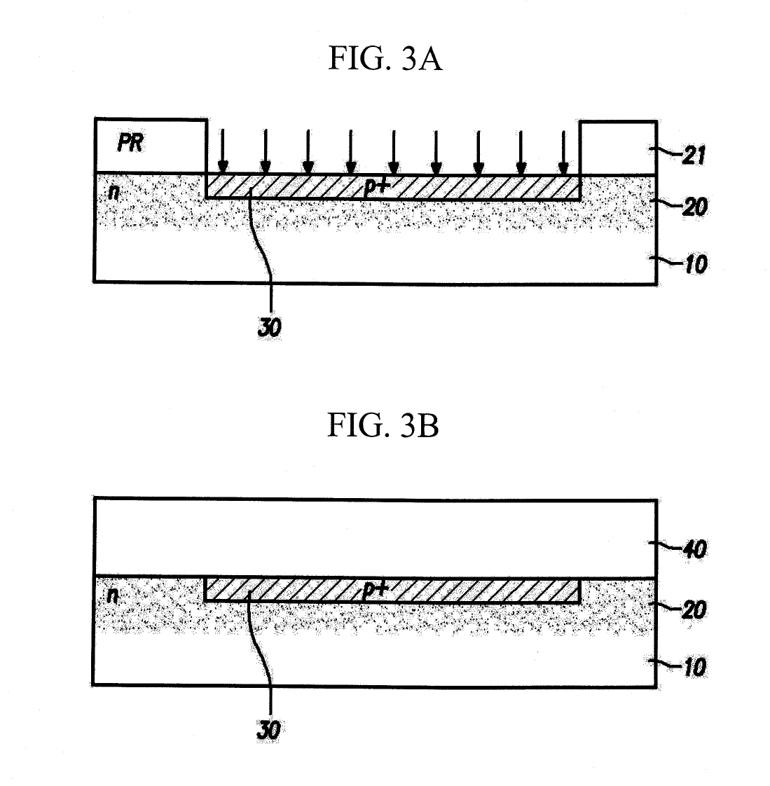

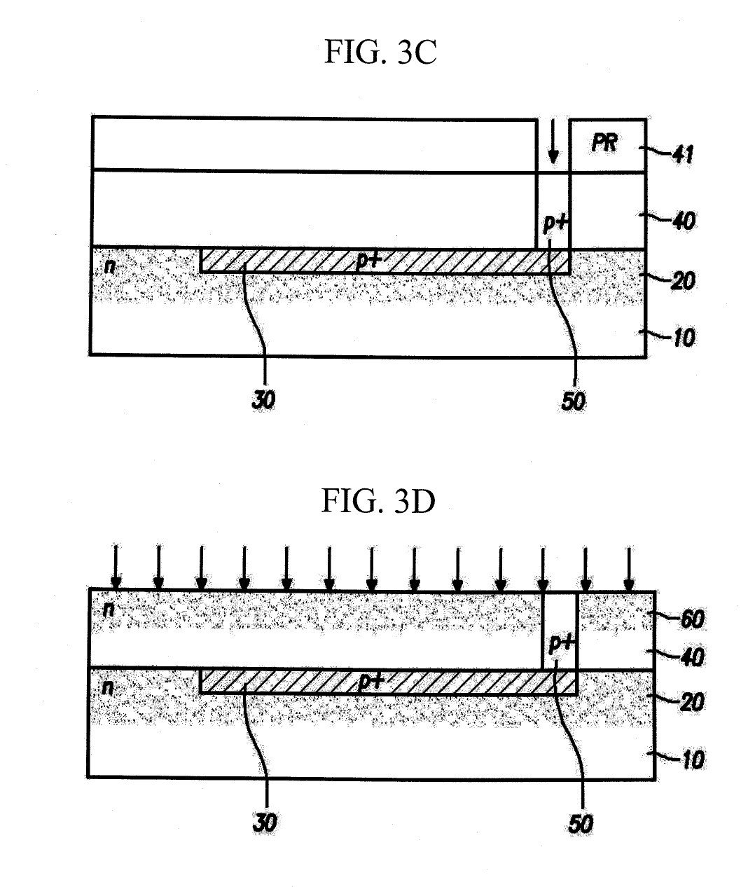

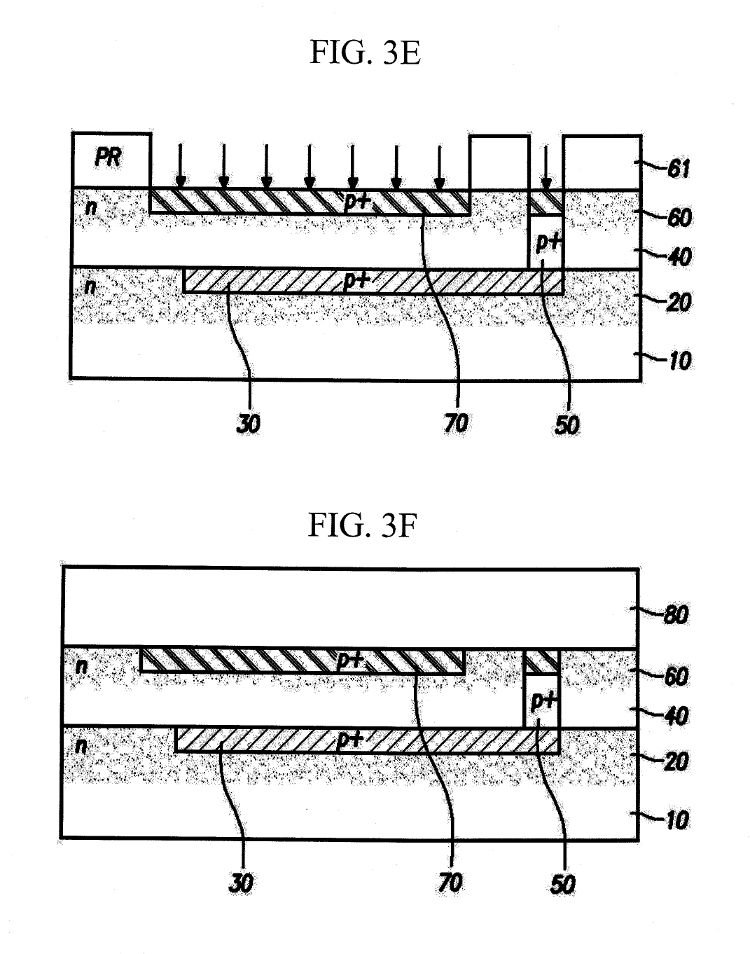

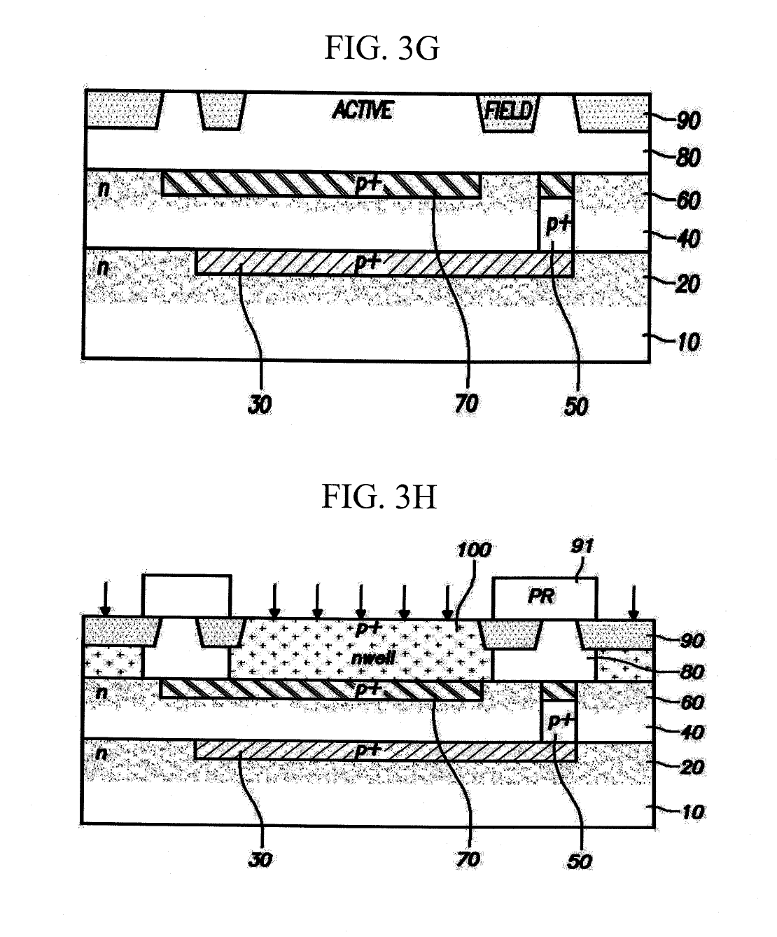

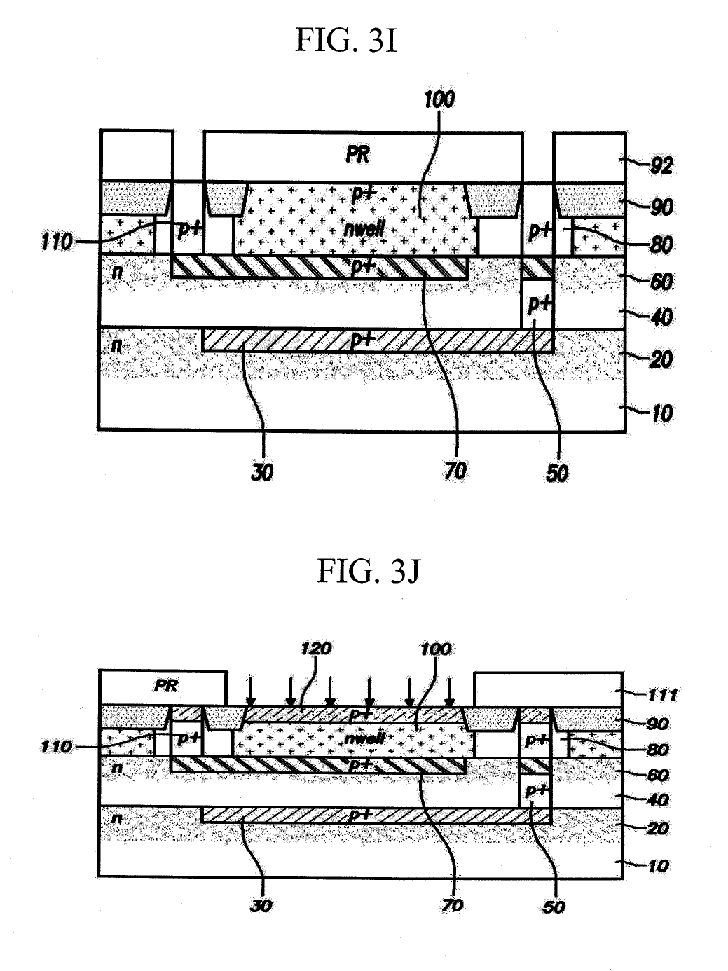

As illustrated in example FIG. 3A, a method of manufacturing a vertical-type CMOS image sensor in accordance with embodiments can include providing N-type semiconductor substrate 10. An n-type dopant can be implanted into the entire surface of semiconductor substrate 10 to form n-type implantation region 20 over the entire surface of the semiconductor substrate 10. First photoresist pattern 21 can be formed on and/or over n-type implantation region 20 excluding a region in which P⁺-type red photodiode 30 will be formed. A dopant for forming P⁺-type red photodiode 30 can then be implanted into n-type implantation region 20 using first photoresist pattern 21.

As illustrated in example FIG. 3B, after forming P⁺-type red photodiode 30 in n-type implantation region 20, an ashing process can be performed to remove first photoresist pattern 21. First silicon epilayer 40 can then be formed on and/or over semiconductor substrate 10 including P⁺-type red photodiode 30 using any one of epitaxial growth processes, including a molecular beam epitaxy (MBE) process using TCS(SiHCl₃) and a vapor phase epitaxy (VPE) process.

As illustrated in example FIG. 3C, after formation of first silicon epilayer 40, second photoresist pattern 41 for forming first P⁺-type plug 50 can be formed on and/or over first silicon epilayer 40. A P⁺-type dopant can then be implanted into first silicon epilayer 40 using second photoresist pattern 41 to form first P⁺-type plug 50. First P⁺-type plug 50 can be formed by selectively implanting metal ions and can be electrically connected to P⁺-type red photodiode 30 and P⁺-type green photodiode 70 which can be formed later.

As illustrated in example FIG. 3D, after formation of first P⁺-type plug 50, second photoresist pattern 41 can be removed. An n-type dopant can then be implanted into the entire surface that is, blanket of first silicon epilayer 40 including first P⁺-type plug 50 to form n-type implantation region 60.

As illustrated in example FIG. 3E, after formation of n-type implantation region 60 in first silicon epi layer 40, third photoresist pattern 61 can be formed for opening a region in which P⁺-type green photodiode 70 can be formed and a region in which first P⁺-type plug 50 can be formed. A dopant for forming P⁺-type green photodiode 70 can then be implanted into n-type implantation region 60 and first P⁺-type plug 50 through third photoresist pattern 61 to form P⁺-type green photodiode 70 in n-type implantation region 60.

As illustrated in example FIG. 3F, after formation of P⁺-type green photodiode 70, an ashing process can then be performed to remove third photoresist pattern 61, and second silicon epilayer 80 can then be formed on and/or over first silicon epilayer 40 including n-type implantation region 60. Second silicon epilayer 80 can be formed using the same epitaxial method as first silicon epilayer 40.

As illustrated in example FIG. 3G, after formation of second silicon epilayer 80, a shallow trench isolation (STI) process can be performed with respect to second silicon epilayer 80 to define an active region and form a plurality of device isolation films 90 for forming field regions.

As illustrated in example FIG. 3H, after formation of device isolation films 90 in second silicon epilayer 80, fourth photoresist pattern 91 for opening the active region between device isolation films 90 can be formed. An n-type dopant can then be implanted through fourth photoresist pattern 91 to form n-well 100.

As illustrated in example FIG. 3I, after formation of n-well 100 in second silicon epilayer 80, fourth photoresist pattern 91 can then be removed. Fifth photoresist pattern 92 can then be formed on and/or over second silicon epi layer 80 in order to form two second P⁺-type plugs 110 respectively connected to P⁺-type green photodiode 70 and first P⁺-type plug 50. A P⁺-type dopant can then be implanted into second silicon epilayer 80 using fifth photoresist pattern 92 to form second P⁺-type plugs 110 respectively connected to P⁺-type green photodiode 70 and first P⁺-type plug 50.

As illustrated in example FIG. 3J, after formation of second P⁺-type plugs 110, an ashing process can then be performed to remove fifth photoresist pattern 92. Sixth photoresist pattern 111 for opening the region of n-well 100 between device isolation films 90 above second silicon epilayer 80 can then be formed. A dopant for forming P⁺-type blue photodiode 120 can then be implanted into the region of n-well 100 between device isolation films 90 using sixth photoresist pattern 111 to form P⁺-type blue photodiode 120.

After formation of P⁺-type blue photodiode 120, sixth photoresist pattern 111 can then be removed using an ashing process. The subsequent processes can be the same as a method of manufacturing typical vertical-type CMOS image sensors. That is, after a process of forming an N⁺-type source/drain region and a process of forming P⁺-type source/drain region are performed, a process of forming a contact and a subsequent back-end-of-layers (BEOL) process can be performed.

Since the vertical-type CMOS image sensor in accordance with embodiments can be connected to transfer gate Tx, the reset transistor, source follower S/F and the select transistor formed of PMOS transistors as illustrated in FIG. 2, it can be possible to prevent occurrence of noise. Since a vertical-type CMOS image sensor having a new pixel structure using a P+N photodiode can be implemented, it can be possible to suppress occurrence of noise and to improve image quality.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate;
a P⁺-type red photodiode formed in the semiconductor substrate;
a first silicon epilayer formed over the semiconductor substrate including the a P⁺-type red photodiode;
a P⁺-type green photodiode formed in the first silicon epilayer;
a second silicon epilayer formed over the first silicon epilayer including the P⁺-type green photodiode;
a P⁺-type blue photodiode formed in the second silicon epilayer;
a first P⁺-type plug formed in the first silicon epilayer and electrically connected at one end to the P⁺-type red photodiode and another end to the P⁺-type green photodiode; and
a second P⁺-type plug formed in the second silicon epilayer and electrically connected to the P⁺-type green photodiode.

2. The apparatus of claim 1, wherein:
the semiconductor substrate and the first silicon epilayer each have n-type implantation regions over the entire surfaces thereof, and
the P⁺-type blue photodiode is formed in an n-well region of the second silicon epi layer.

3. The apparatus of claim 1, wherein the P⁺-type red photodiode, the P⁺-type green photodiode and the P⁺-type blue photodiode comprise P+N photodiodes.

4. The apparatus of claim 2, wherein the P⁺-type red photodiode, the P⁺-type green photodiode and the P⁺-type blue photodiode comprise P+N photodiodes.

5. The apparatus of claim 1, wherein further comprising:
a first plug formed in the first silicon epilayer electrically connected to the P⁺-type red photodiode and the P⁺-type green photodiode; and
a pair of second plugs formed in the second silicon epilayer and electrically connected to the P⁺-type green photodiode and the first plug.

6. A method comprising:
forming a first n-type implantation region in the semiconductor substrate by implanting an n-type dopant into the entire surface of the semiconductor substrate;
forming a P⁺-type red photodiode in the first n-type implantation region by implanting a dopant therein;
forming a first silicon epilayer over the semiconductor substrate including the P⁺-type red photodiode using an epitaxial growth method;
forming a first P⁺-type plug extending through the first silicon epilayer and electrically connected to the P⁺-type red photodiode;
forming a second n-type implantation region in the first silicon epilayer by implanting an n-type dopant into the entire surface of the first silicon epilayer including the first P⁺-type plug;
forming a P⁺-type green photodiode in the second n-type implantation region by implanting a dopant therein;
forming a second silicon epilayer over the first silicon epilayer including the P⁺-type green photodiode;
performing a shallow trench isolation on the second silicon epilayer to define an active region and form a plurality of device isolation films for forming field regions;
forming a plurality of n-well regions by implanting an n-type dopant into the active region between the device isolation films;
forming a pair of second P⁺-type plugs extending through the second silicon epilayer and electrically connected to the P⁺-type green photodiode and the first P⁺-type plug by implanting a P⁺-type dopant into the second silicon epilayer; and then
forming a P⁺-type blue photodiode in the second silicon epilayer by implanting a dopant into one of the n-well regions between the device isolation films.

7. The method of claim 6, wherein the P⁺-type red photodiode, the P⁺-type green photodiode and the P⁺-type blue photodiode comprise P+N photodiodes.

8. The method of claim 6, wherein the first silicon epilayer and the second silicon epilayer are formed using at least one of a molecular beam epitaxy process and a vapor phase epitaxy process.

9. A method comprising:
forming a first n-type implantation region in a semiconductor substrate;
forming a first photodiode in the first n-type implantation region;
forming a first silicon epilayer over the semiconductor substrate including the first photodiode;
forming a first plug in the first silicon epilayer and electrically connected to the first photodiode;
forming a second n-type implantation region in the first silicon epilayer;
forming a second photodiode in the second n-type implantation region and electrically connected to the first plug;
forming a second silicon epilayer over the first silicon epilayer including the n-type implantation region and the second photodiode;
forming a plurality of device isolation films in the second silicon epilayer;
forming a plurality of n-type well regions in the second silicon epilayer;
forming a pair of second plugs in the second silicon epilayer and electrically connected to second photodiode and first plug; and then forming a third photodiode in one of the n-well regions.

10. The method of claim 9, wherein forming the first n-type implantation region comprises implanting an n-type dopant into the entire surface of the semiconductor substrate.

11. The method of claim 9, wherein forming the first photodiode comprises implanting a P⁺-type dopant into the first n-type implantation region.

12. The method of claim 11, wherein the first photodiode comprises a P⁺-type red photodiode.

13. The method of claim 9, wherein forming the first silicon epilayer is performed using at least one of a molecular beam epitaxy process and a vapor phase epitaxy process.

14. The method of claim 9, wherein forming the first plug comprises implanting a P⁺-type dopant into the first silicon epilayer and forming the second plugs comprises implanting a P⁺-type dopant into the second silicon epilayer.

15. The method of claim 9, wherein forming the n-type implantation region comprises implanting an n-type dopant into the entire surface of the first silicon epilayer.

16. The method of claim 9, wherein forming the second photodiode comprises implanting a P⁺-type dopant into the second n-type implantation region and the first plug.

17. The method of claim 16, wherein the second photodiode comprises a P⁺-type green photodiode.

18. The method of claim 9, wherein forming the plurality of device isolation films comprises performing a shallow trench isolation process on the second silicon epilayer to define an active region.

19. The method of claim 9, wherein forming the third photodiode comprises implanting a P⁺-type dopant into one of the n-well regions.

20. The method of claim 19, wherein the third photodiode comprises a P⁺-type blue photodiode.
